(19) United States
(12) Patent Application Publication
(10) Pub. No.: US 2004/0214413 A1
(43) Pub. Date: Oct. 28, 2004

(54) Semiconductor device manufacturing method and film forming method

(75) Inventors: Tomoyasu Nakamine, Hitachinaka (JP); Kenichi Yamaguchi, Hachiouji (JP); Kenichi Satoh, Hitachinaka (JP)

Correspondence Address: Stanley P. Fisher, Reed Smith, Suite 1400, 3110 Fairview Park Drive, Fallls Church, VA, 22042-0681, US

(73) Assignee: Trecenti Technologies, Inc.

(21) Appl. No.: 10/829,382

(22) Filed: Apr. 22, 2004

(30) Foreign Application Priority Data
Apr. 25, 2003 (JP) P2003-120855

(51) Int. Cl. H01L 21/20

(52) U.S. Cl. 438/485; 438/788; 438/792

(57) ABSTRACT

By-products inside a furnace body of a CVD film forming apparatus after gas cleaning is performed in the furnace body are provided from being generated. The gas cleaning is performed in the furnace body by a plasma of a gas containing a halogen system gas and an Ar gas in an atmosphere in which the temperature of a heater disposed in the furnace body is approximately 500° C. or lower. Thereafter, a rise of the temperature of the heater is started. While the temperature of the heater is maintained constant, a film forming gas is introduced into the furnace body during a time period before the raised temperature reaches a temperature at which radicals or ions of a halogen system element are activated. Thereby, thin films are formed on the inner wall of the furnace body and the surfaces of members including the heater in the furnace body

### CROSS-REFERENCE TO RELATED APPLICATION

The present application claims priority from Japanese patent application No. JP 2003-120855 filed on Apr. 25, 2003, the content of which is hereby incorporated by reference into this application.

### BACKGROUND OF THE INVENTION

The present invention relates to a semiconductor device manufacturing technique and a film forming technique and, more specifically, to a technique effectively applicable to a thin film forming process using a CVD (Chemical Vapor Deposition) film forming apparatus.

For example, in the CVD film forming apparatus, there is a technique for: cleaning, by a ClF₃ gas, the interior of a chamber to which a film forming process is performed; thereafter forming, in the chamber, a plasma including an Ar (argon) gas and a reducing gas; removing, using this plasma, accretions each made of an AlF (aluminum fluoride) system substance and attached to an inner wall of the chamber and/or to surfaces of members located in the chamber; and preventing the film from peeling off at the time of performing a pre-coating process in the chamber (see, for example, Japanese Patent Laid-Open No. 2002-167673).

### SUMMARY OF THE INVENTION

The present inventors have examined techniques for forming a thin film on a semiconductor wafer (hereinafter abbreviated as “wafer”) by using the CVD film forming apparatus and found out the following problems.

That is, after a thin film is formed on a wafer by using the CVD film forming apparatus, it covers the inner wall of a furnace body (chamber) in the CVD film forming apparatus and the surfaces of members located inside the furnace body besides the surface of the wafer. Therefore, after the thin film forming process is performed to the predetermined number of wafers, for example, gas cleaning is performed using a halogen system gas in order to remove the thin films attached to the inner wall of the furnace body and to the members located inside the furnace body. In this gas cleaning, a plasma of the halogen system gas is formed and the thin films attached to the inner wall of the furnace body and to the members located inside the furnace body are removed by the plasma. Furthermore, when the film forming temperature inside the furnace body at the time of forming the thin film is approximately 600° C. or higher, the gas cleaning is performed after the temperature inside the furnace body is lowered up to the temperature at which there occurs no chemical reaction of radicals or ions of halogen system element formed by decomposition of the halogen system gas and of the members located inside the furnace body, for example, up to approximately 500° C. lower. Then, after the gas cleaning is completed, the temperature inside the furnace body is again raised to approximately 600° C. or higher, and thereafter the film forming process is performed to the wafer.

The radicals or ions of the halogen system element formed by the decomposition of the above-mentioned halogen system gas are left inside the furnace body even after the gas cleaning. For this reason, the inventors have found that: when the temperature inside the furnace body is raised after the gas cleaning, the chemical reaction of the members disposed inside the furnace body (for example, a heater on which the wafer is placed) and of the radicals or ions of the halogen system elements progresses by the heating; by-products are generated by the chemical reaction; the by-products are attached to the inner wall of the furnace body and to the members located inside the furnace body. Under the condition that the by-products are attached to the inner wall of the furnace body and the members located inside the furnace body, for example, there are the drawbacks of: a failure of the CVD film forming apparatus, such as a decrease of temperature in the heater placed inside the furnace body; occurrence of a variation in the thickness of the thin film formed on the surface of the wafer; and degradation in film quality of the thin film due to the by-products dispersed as foreign substances in the furnace body and attached to the wafer. Therefore, there is the problem that a stable operation of the CVD film forming apparatus and quality of the manufactured semiconductor device cannot be maintained.

An object of the present invention is to provide a technique capable of preventing the occurrence of the by-products inside the furnace body of the CVD film forming apparatus after the gas cleaning is performed inside the furnace body.

The above and other objects and novel features will be apparent from the description of the specification and the accompanying drawings.

Outlines of the representative ones of the inventions disclosed in this application will be briefly described as follows.

That is, the present invention is a semiconductor device manufacturing method using a film forming apparatus having a film forming chamber for performing a film forming process to a semiconductor substrate or other substrate, the film forming apparatus performing said film forming process at a first temperature, and including a step of forming a first thin film over said semiconductor substrate or other substrate, the method comprising the steps of:

after forming said first thin film over a predetermined number of said semiconductor substrates or other substrate,

(a) decreasing a temperature in said film forming chamber up to a second temperature lower than said first temperature;

(b) after said step (a), forming a plasma from a gas containing a halogen system gas, and removing an accretion attached in said film forming chamber by using said plasma; and

(c) after said step (b), cleaning an interior of said film forming chamber in a step of raising the interior of said film forming chamber up to said first temperature,

wherein said film forming apparatus has, in said film forming chamber, a first member reacting with a halogen system element and generating a by-product, and

the method further comprises the step of:

forming a second thin film on an inner wall of said film forming apparatus and on a surface of a member provided in said film forming chamber at the same temperature as that after said accretion is removed in said step (b) or at a temperature before the interior of said film forming chamber reaches said first temperature in said step (c).

### BRIEF DESCRIPTION OF THE DRAWINGS

FIG. 1 is a sectional view showing a principal portion of a film forming apparatus used for a semiconductor device manufacturing process according to one embodiment of the present invention.

FIG. 2 is an explanatory view showing a temperature change in a furnace body in the film forming apparatus used for the semiconductor device manufacturing process according to one embodiment of the present invention until an interior of the furnace body is subjected to gas cleaning and a film forming process is resumed.

FIG. 3 is an explanatory view showing a relation between the cumulative number of wafers subjected to a film forming process performed by a film forming apparatus which is compared to the film forming apparatus used for the semiconductor device manufacturing process according to one embodiment of the present invention and an average value of the thicknesses of the formed thin films.

FIG. 4 is an explanatory view showing a relation between the cumulative number of wafers subjected to the film forming process performed by the film forming apparatus used for the semiconductor device manufacturing process according to one embodiment of the present invention and an average value of the thicknesses of the formed thin films.

FIG. 5 is a sectional view showing a principal portion of a semiconductor device in the semiconductor device manufacturing process according to one embodiment of the present invention.

FIG. 6 is a sectional view showing a principal portion of the semiconductor device in the manufacturing process subsequent to FIG. 5.

FIG. 7 is a plan view showing a principal portion of a semiconductor device in the manufacturing process according to one embodiment of the present invention.

FIG. 8 is a sectional view showing a principal portion of the semiconductor device in the manufacturing process subsequent to FIG. 6.

FIG. 9 is a sectional view showing a principal portion of the semiconductor device in the manufacturing process subsequent to FIG. 8.

FIG. 10 is a plan view showing a principal portion of a semiconductor device in a manufacturing process according to one embodiment of the present invention.

FIG. 11 is a sectional view showing a principal portion of the semiconductor device in the manufacturing process subsequent to FIG. 9.

FIG. 12 is a sectional view showing a principal portion of the semiconductor device in the manufacturing process subsequent to FIG. 11.

FIG. 13 is a plan view showing a principal portion of a semiconductor device in a manufacturing process according to one embodiment of the present invention.

FIG. 14 is a sectional view showing a principal portion of the semiconductor device in the manufacturing process subsequent to FIG. 12.

FIG. 15 is a sectional view showing a principal portion of the semiconductor device in the manufacturing process subsequent to FIG. 14.

FIG. 16 is a sectional view showing a principal portion of the semiconductor device in the manufacturing process subsequent to FIG. 15.

FIG. 17 is a sectional view showing a principal portion of the semiconductor device in the manufacturing process subsequent to FIG. 16.

### DESCRIPTION OF THE PREFERRED EMBODIMENTS

Hereinafter, embodiments of the present invention will be detailed based on the drawings. Note that, through all of the drawings for describing the embodiments, members having the same function are denoted by the same reference symbol and the repetitive explanation thereof will be omitted.

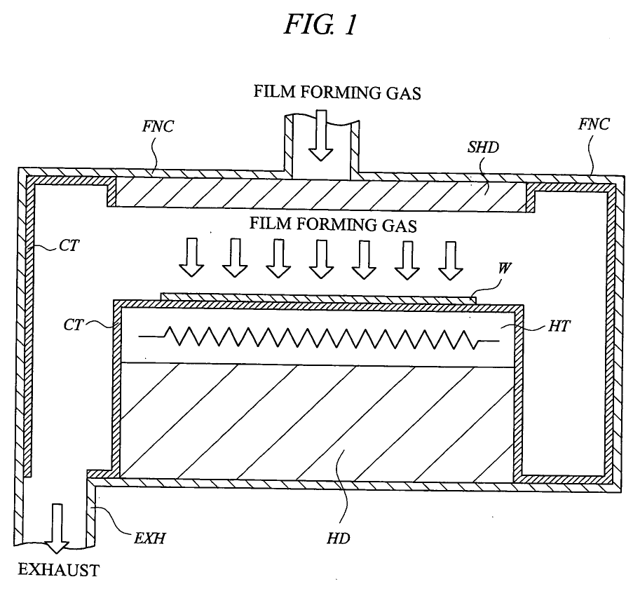

FIG. 1 is a sectional view showing a principal portion of an example of a CVD film forming apparatus used for an embodiment of the present invention. The CVD film forming apparatus according to the present embodiment performs a film forming process to a wafer (semiconductor substrate) W by using, for example, a single wafer processing through a CVD method (chemical film forming method). The CVD film forming apparatus includes an airtight furnace body (film forming chamber) FNC made of Al (aluminum) or the like. In the furnace body FNC, the wafer W to be subjected to the film forming process and a heater (first member) HT for heating an atmosphere in the furnace body FNC at the predetermined temperature are disposed so as to be supported by a supporting member HD. The heater HT is made of Al system ceramic or the like, and also has a function as a susceptor for horizontally supporting the wafer W in the furnace body FNC. Also, the furnace body FNC is provided with an exhaust mechanism EXH. Therefore, during the film forming process, the interior of the furnace body FNC can be reduced up to the predetermined degrees of vacuum by operating this exhaust mechanism EXH.

From a shower head SHD disposed on a ceiling wall of the furnace body FNC, a film forming gas is supplied to the wafer W placed on the heater HT. The film forming gas initiates a chemical reaction with the surface of the wafer W by the heating from the heater HT. By dissociation or combination of the film forming gas associated with this chemical reaction, a thin film is deposited on the wafer W.

In the present embodiment, the thin film (first thin film) formed by the CVD film forming apparatus illustrated in FIG. 1 is a thin film formed in an atmosphere in which the interior of the furnace body FNC has a temperature (first temperature) of approximately 600° C. or higher. Examples of such a thin film are an epitaxial Si (silicon) film, an amorphous Si film, a polycrystalline Si film, a Si nitride film, and a Si oxide film, etc. Hereafter, the case where the thin film is a Si nitride film will be described by way of example.

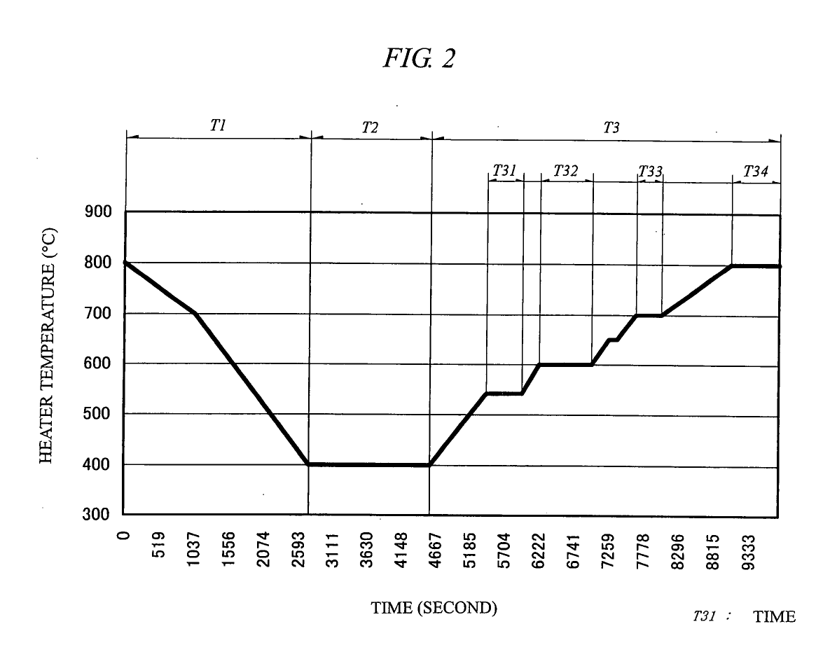

After the CVD film forming apparatus according to the present embodiment is used to perform the film forming process of a Si nitride film to the wafer W, the Si nitride film is caused to be formed on not only the wafer W but also the inner wall of the furnace body FNC and on the surfaces of members such as the heater HT located inside the furnace body FNC. There is the problem that the Si nitride films having been formed on the inner wall of the furnace body FNC and on the surfaces of the members such as the heater HT located inside the furnace body FNC may be peeled off, for example, at the time of performing the film forming process to another wafer W, and the peeled film may be attached as foreign substances to the wafer W. There is also the problem that if the thin film like a Si nitride film is formed on the inner wall of the furnace body FNC and on the surfaces of the members such as the heater HT located inside the furnace FNC, a film forming capability of the CVD film forming apparatus may degrade. Therefore, after the film forming process of a Si nitride film has been performed to the predetermined number (for example, approximately 100) of wafers W, the gas cleaning is performed by using, for example, a halogen system gas, in order to remove the Si nitride films (accretions) attached to the inner wall of the furnace body FNC and to the surfaces of the members located inside the furnace body FNC. Furthermore, after the film forming process of a Si nitride film is performed to the predetermined number (for example, approximately 10000) of wafers W, cleaning of the entire interior of the furnace body FNC (hereinafter referred to as “entire furnace-body cleaning”) is performed. Now, a step, from the gas cleaning employing a halogen system gas to the fact that the film forming process of a Si nitride film is resumed to the wafer W, will be described with reference to FIG. 2.

FIG. 2 is a view showing a temperature change of the interior of the furnace body FNC in course of the following processes: the temperature inside the furnace body FNC is lowered to perform the gas cleaning to the interior of the furnace body FNC; the gas cleaning is performed; the temperature inside the furnace body FNC is raised up to the temperature at which the film forming process is performed again; and then the film forming process is resumed. In the present embodiment, since the temperature inside the furnace body FNC is changed and determined by the temperature of the heater HT, the temperature of the heater HT in FIG. 2 is indicated as that inside the furnace body FNC. Also, hereafter, the temperature of the heater HT will be described as that inside the furnace body FNC.

As illustrated in FIG. 2, in the present embodiment, the temperature of the heater HT is lowered in a time period T1 from a temperature of approximately 800° C. which is the temperature of the film forming process of a Si nitride film, to a temperature of approximately 500° C. or lower (second temperature), preferably approximately 400° C. (second temperature). Then, under the condition that the temperature of the heater HT is set at, for example, approximately 400° C., the gas cleaning is performed to the interior of the furnace body FNC in a time period T2. Next, the temperature of the heater HT is raised in a time period T3 from approximately 400° C. to approximately 800° C. at which the thin film forming process of a Si nitride film is performed.

The above-mentioned gas cleaning is one in which: a gas plasma including a halogen system gas such as ClF₃, CF₄, CF₃, or NF₃ (the gas contains, as a composition(s), either or both of Cl (chlorine) and F (fluorine)) and an Ar (argon) gas is produced inside the furnace body FNC; by using this plasma, the thin films attached to the inner wall of the furnace body FNC and to the surfaces of the members located inside the furnace body FNC are etched; and thereby the thin films are removed. At this time, if the gas cleaning is performed under the condition that the temperature of the heater HT is approximately 500° C. or higher, radicals or ions of a halogen system element generated due to dissociation of the above-mentioned halogen system gas are activated and react with, for example, Al system ceramic of which the heater HT (first member) is made, whereby by-products are generated. When a NF₃ gas is used as the halogen system gas, this reaction is represented by a chemical equation of:

AlN+F*→AlF₃+N₂ or AlN+F⁻→AlF₃+N₂,

where the chemical symbol “AlF₃” corresponds to the by-product thereof. Note that, in this chemical equation, the chemical symbol “F*” represents a radical of “F”. If such by-products are attached to the inner wall of the furnace body FNC and the members located inside the furnace body FNC, for example, there arises the problem of: the failure of the CVD film forming apparatus, such as a decrease in temperature in the heater HT; occurrence of the variation in the thickness of the Si nitride film formed on the surface of the wafer W; and degradation in film quality of the thin film due to the fact that the by-products are dispersed as foreign substances inside the furnace body FNC and attached to the wafer W. Also, there is the problem that when activated, the radicals or ions of the halogen system element react with the inner wall (first member) of the furnace body FNC and other members (first member) located inside the furnace body FNC, thereby damaging the furnace body FNC and other members located inside the furnace body FNC. For this reason, in the present embodiment, the temperature of the heater HT is lowered up to a temperature of approximately 500° C. or lower at the time of the gas cleaning.

Furthermore, the inventors have found that part of the radicals or ions of the above-mentioned halogen system element is left inside the furnace body FNC even after the above-mentioned gas cleaning, and cannot be completely removed even by charging an inert gas (for example, a N₂ (nitride) gas) into the furnace body FNC. Therefore, there is are the problems that: when the temperature inside the furnace body FNC is raised after the gas cleaning, the radicals or ions are activated and react with Al system ceramic, of which the heater HT is made, and by-products may be generated; and the radicals or ions may react with the inner wall of the furnace body FNC and other members located inside the furnace body FNC and damage the furnace body FNC itself and the other members located inside the furnace body FNC. Therefore, in the present embodiment, a film forming gas is introduced into the furnace body FNC during the above-mentioned time period T3, and a thin film (second thin film) CT (see FIG. 1) is formed on the inner wall of the furnace body FNC and on the surfaces of the members located inside the furnace body FNC, whereby the inner wall of the furnace body FNC and the surfaces of the members located inside the furnace body FNC are covered with the thin films CT. This can prevent the inner wall of the furnace body FNC and the members located inside the furnace body FNC from reacting with the radicals or ions of the halogen system element. At this time, the thin film CT is formed preferably when the temperature of the heater HT is as low as possible so that the radicals or ions of the halogen system element are not activated as much as possible. In the present embodiment, an example of a temperature of approximately 600° C. or lower (third temperature) is given as the preferable one. That is, as illustrated in FIG. 2, a rise of the temperature of the heater HT is started, and when the temperature reaches approximately 540° C., the temperature of the heater HT is maintained at approximately 540° C. during a time period T31 to introduce a SiH₄ gas into the furnace body FNC. Due to this, an amorphous Si film is formed on the inner wall of the furnace FNC and on the members (including the heater HT) located inside the furnace body FNC. After forming such an amorphous Si film, the temperature of the heater HT is raised again and, when reaching approximately 600° C., the temperature of the heater HT is maintained at approximately 600° C. during a time period T32 and, by again introducing the SiH₄ gas into the furnace body FNC, a further amorphous Si film may be formed on the surface of the amorphous Si film previously formed. Thus, by forming a plurality of amorphous Si films on the inner wall of the furnace body FNC and on the surfaces of the members located inside the furnace body FNC, the inner wall of the furnace body FNC and the surfaces of the members located inside the furnace body FNC can be more certainly covered with the amorphous Si films, in comparison with the case of only the single amorphous Si film. Therefore, it is possible to prevent more effectively the inner wall of the furnace body FNC and the members located inside the furnace body FNC from reacting with the radicals or ions of the halogen system element. Additionally, the description in the present embodiment has been made to the case where the amorphous Si film is formed on the inner wall of the furnace body FNC and on the surfaces of the members located inside the furnace body FNC under the condition that the temperature of the heater HT is set at approximately 600° C. or lower. However, a thin film other than the amorphous Si film may be formed if it can be formed under the condition that the temperature thereof is approximately 600° C. or lower.

After forming the above-mentioned amorphous Si film, a polycrystalline Si film may be laminated further on the surface of the above-mentioned amorphous Si film by: again raising the temperature of the heater HT from approximately 600° C. to approximately 700° C.; then maintaining the temperature of the heater HT at approximately 700° C. during a time period T33; and again introducing a SiH₄ gas into the furnace body FNC. At this time, due to the heating from the heater HT, the underlying amorphous Si film of the polycrystalline Si film is changed to a polycrystalline silicon film. Thereafter, a Si nitride film may be laminated on the surface of the polycrystalline Si film by: again raising the temperature of the heater HT from approximately 700° C. to approximately 800° C. at which the film forming process of a Si nitride film is performed to the wafer W; then maintaining the temperature of the heater HT at approximately 800° C. during a time period T34; and introducing a SiH₄ gas and a NH₃ gas into the furnace body FNC. Thus, by forming, on the inner wall of the furnace body FNC and on the surfaces of the members located inside the furnace body FNC, thin films of types capable of being formed in accordance with the rise of the temperature of the heater HT, the inner wall of the furnace body FNC and the surfaces of the members located inside the furnace body FNC can be much certainly covered with the thin films CT. Due to this, it is possible to certainly prevent the inner wall of the furnace body FNC and the members located inside the furnace body FNC from reacting with the radicals or ions of the halogen system element. Furthermore, when the inner wall of the furnace body FNC and the surfaces of the members located inside the furnace body FNC are covered with the plurality of thin films CT, the uppermost film of the plurality of thin films CT is preferably a thin film (Si nitride film) to be formed on the wafer W. Further, in the case of covering the inner wall of the furnace body FNC and the surfaces of the members located inside the furnace body FNC with a single thin film CT, if the single film can be formed under the condition that the temperature of the heater HT is approximately 600° C. or lower, the single film is preferably a thin film of the same type as that of the thin film (Si nitride film) to be formed on the wafer W.

Furthermore, in the CVD film forming apparatus according to the present embodiment, since the above-mentioned by-products can be prevented from being generated in the furnace body FNC, it is possible to prevent the problems arising in the CVD film forming apparatus, for example, the problems that the temperature of the heater HT is decreased due to the by-products attached to the heater HT. Therefore, the stable operation of the CVD film forming apparatus according to the present embodiment can be ensured. Additionally, since the above-mentioned by-products are prevented from being generated in the furnace body FNC, contamination in the furnace body FNC can be prevented. Due to this, the frequency of performing the entire furnace-body cleaning in the furnace body FNC can be reduced. As a result of this, it is possible to reduce an operation stop time of the CVD film forming apparatus caused by the problems arising in the CVD film forming apparatus or by performing the entire furnace-body cleaning. Further, since the contamination in the furnace body FNC is prevented, it is possible to prevent the problems that the foreign substances are produced in the furnace body FNC while the film forming process of a Si nitride film is performed to the wafer W, whereby the film quality of the Si nitride film is reduced. Therefore, degradation in quality of the semiconductor device manufactured from the wafer W can be prevented.

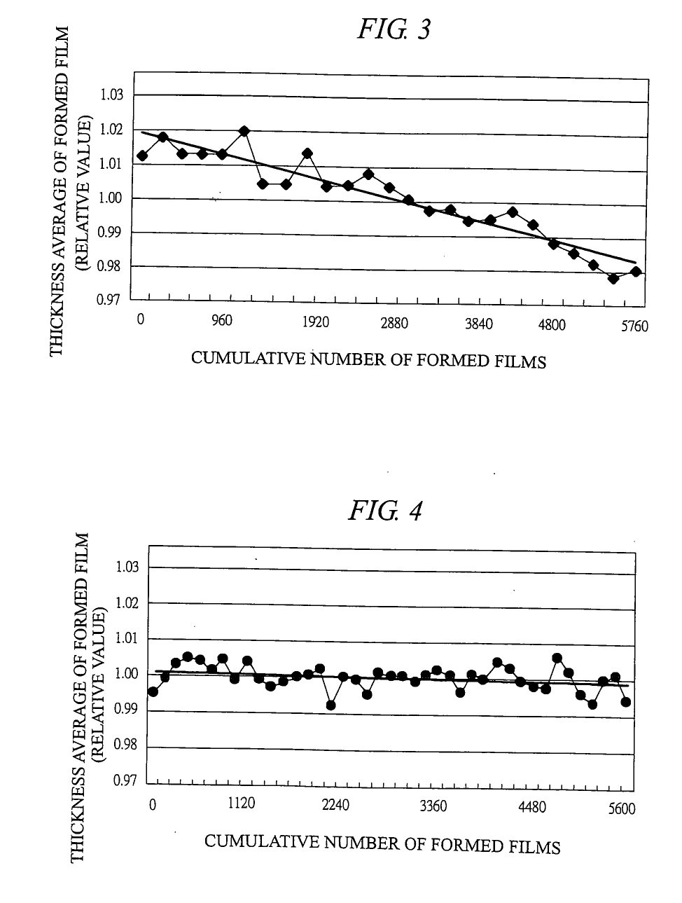

Here, FIGS. 3 and 4 illustrate results obtained through the experiments by the inventors with regard to a relation between the cumulative number of wafers W, to which the CVD film forming apparatus performs the film forming process of a Si nitride film, and an average value (relative value) of the thicknesses of the Si nitride films formed on these wafers, wherein FIG. 3 illustrates the case where the above-mentioned thin film CT is not formed on the inner wall of the furnace body FNC and the surfaces of the members located inside the furnace body FNC during the above-mentioned time period T3 and FIG. 4 illustrates the case where the above-mentioned thin film CT is formed thereon.

As illustrated in FIG. 3, when the above-mentioned thin film CT is not formed on the inner wall of the furnace body FNC and on the surfaces of the members located inside the furnace body FNC during the time period T3, the average thickness of the formed Si nitride film decreases in accordance with an increase in the cumulative number of wafers W to which the film forming process of a Si nitride film is performed. That is, as the number of the wafers W processed by the CVD film forming apparatus increases, to form a Si nitride film having the predetermined thickness becomes difficult. In contrast, as illustrated in FIG. 4, in the case where the above-mentioned thin film CT is formed on the inner wall of the furnace body FNC and on the surfaces of the members located inside the furnace body FNC during the time period T3, even if the cumulative number of the wafers W subjected to the film forming process of a Si nitride film increases, the average thickness of the formed Si nitride films is approximately constant. That is, according to the CVD film forming apparatus of the present embodiment, in which the thin films are formed on the inner wall of the furnace body FNC and on the surfaces of the members located inside the furnace body FNC during the time period T3, the Si nitride film having the predetermined thickness can be formed even if the cumulative number of the wafers W subjected to the film forming process of the Si nitride film is increased.

Also, the inventors have studied, through experiments, a relation between the cumulative number of the wafers W, to which the CVD film forming apparatus performs the film forming process of the Si nitride film, and an amount of the variation of uniformity of the thickness of the Si nitride film within a film forming surface (main surface (device forming surface)), with regard to the case where the above-mentioned thin films CT are not formed on the inner wall of the furnace body FNC and on the surfaces of the members located inside the furnace body FNC during the above-mentioned time period T3 and the case where the above-mentioned thin films CT are formed thereon. As a result, in the case where the thin films CT were not formed on the inner wall of the furnace body FNC and on the surfaces of the members located inside the furnace body FNC during the time period T3, the uniformity of the thickness of the Si nitride film, formed on the wafer W at the time when the cumulative number of the wafers W reached approximately 2000, was varied by approximately 1.5% in comparison with that at the time when the film forming process to the wafer W was started. In contrast, in the case where the thin films CT were formed on the inner wall of the furnace body FNC and on the surfaces of the members located inside the furnace body FNC during the time period T3, the uniformity of the thickness of the Si nitride film, formed on the wafer W at the time when the cumulative number of the wafers W reached approximately 2000, was almost unchanged and is equal to almost 0% in comparison with that at the time when the film forming process to the wafer W was started. If the uniformity of the thickness of the Si nitride film within the film forming surface of the wafer W is not varied with the increase in the cumulative number of the wafers W, no such variation means that the CVD film forming apparatus can continue the film forming process of the Si nitride film under the predetermined film forming process condition even if the cumulative number of the wafers is increased. That is, according to the CVD film forming apparatus of the present embodiment, it is possible to reduce the frequency of performing the above-described gas cleaning in the furnace body FNC and the frequency of performing the above-described entire furnace-body cleaning. As a result, it is possible to reduce the operation stop time of the CVD film forming apparatus, due to the gas cleaning of the furnace body FNC and the entire furnace-body cleaning. Also, as the diameter of the wafer W increases, the uniformity of the thickness of the Si nitride film within the film forming surface of the wafer W decreases. Therefore, in the case of performing the film forming process of the Si nitride film by using the CVD film forming apparatus in which the thin films CT are not formed on the inner wall of the furnace body FNC and on the surfaces of the members located inside the furnace body FNC during the time period T3, as the diameter of the wafer W increases, the amount of the variation in the uniformity of the thickness of the Si nitride film also increases. For this reason, by using the CVD film forming apparatus according to the present embodiment in which the thin films CT are formed on the inner wall of the furnace body FNC and on the surfaces of the members located inside the furnace body FNC during the time period T3, to perform the film forming process of the Si nitride film to the wafer W having a large diameter of, for example, approximately 300 mm is especially effective in that the variation in the uniformity of the thickness of the Si nitride film is suppressed.

In the present embodiment as mentioned above, there has been described, by way of example, the case where the film forming process of the Si nitride film is performed to the wafer W under the condition that the temperature of the heater HT is approximately 800° C. However, even in the case of a thin film, such as an epitaxial Si film, an amorphous Si film, a polycrystalline Si film, and a Si oxide film, other than the Si nitride film formed in a high temperature atmosphere where the temperature in the furnace body FNC (the temperature of the heater HT) is approximately 600° C. or higher, there arise, in the CVD film forming apparatus, the same problems as those arising in the case where the Si nitride film is formed at the time of performing the gas cleaning in the furnace body FNC and then raising the temperature of the heater HT from approximately 400° C. to the temperature (approximately 600° C. to 900° C.) at which the film forming process is performed. Therefore, even in the case where a thin film other than the Si nitride film is formed in such a high temperature atmosphere, while the temperature of the heater HT is raised from approximately 400° C. to the temperature at which the film forming process is performed similarly to the case of forming the Si nitride film, the thin films CT are formed on the inner wall of the furnace body FNC and on the surfaces of the members located inside the furnace body FNC at the time when the temperature of the heater HT is as low as possible, for example, approximately 600° C. or higher, whereby the inner wall of the furnace body FNC and the surfaces of the members located inside the furnace body FNC are covered with the thin films CT. Also, until the temperature of the heater HT reaches the temperature at which the film forming process to the wafer W is performed, thin films of types capable of being formed in accordance with the rise of the temperature of the heater HT may be sequentially formed on the inner wall of the furnace body FNC and on the surfaces of the members located inside the furnace body FNC. By doing so, even when a thin film other than the Si nitride film is formed on the wafer W in the high temperature atmosphere, it is possible to prevent the by-products from being generated by the fact that the Al system ceramic, of which the heater HT is made, reacts with the radicals or ions of the halogen system element, and to prevent the inner wall of the furnace body FNC and other members located inside the furnace body FNC from being damaged by the fact that the Al system ceramic reacts with them. Furthermore, in the case where the inner wall of the furnace body FNC and the surfaces of the members located inside the furnace body FNC are covered with the plurality of thin films CT, the uppermost thin film CT of the plurality of thin films CT is preferably a thin film formed on the wafer W similarly to the case of performing the thin forming process of a Si nitride film to the wafer W. Additionally, when the inner wall of the furnace body FNC and the surfaces of the members located inside the furnace body FNC are covered with the single thin film CT, the single film is preferably a thin film of the same type as that of the thin film to be formed on the wafer W if the single film can be formed under the condition that the temperature of the heater HT is approximately 600° C. or lower.

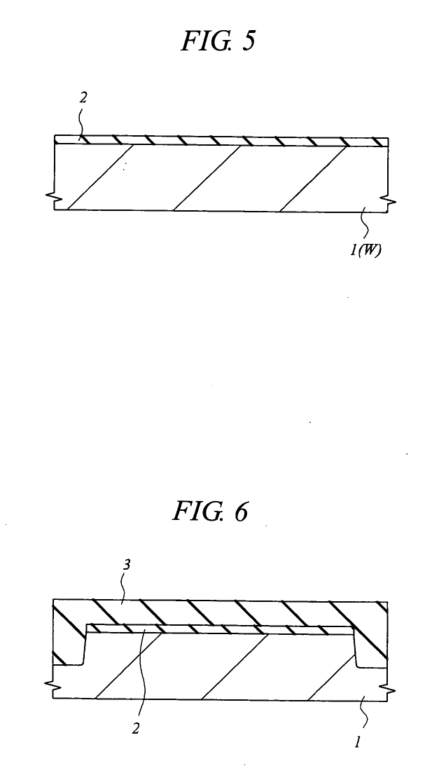

Next, a semiconductor device manufacturing process according to the present embodiment will be described with reference to FIGS. 5 through 17. Of these drawings used in describing the semiconductor device manufacturing process according to the present embodiment, each plan view is an example of an enlarged plan view showing a principal portion for describing the manufacturing process. Also, each sectional view is an example of an enlarged sectional view showing a principal portion for describing the manufacturing process, or a view showing a section taken along line A-A in the plan view for describing the corresponding process. Further, through the drawings used in describing the semiconductor device manufacturing process according to the present embodiment, even the plan view is hatched in some cases to understand more easily the structures of members.

A semiconductor device of the present embodiment includes a CMIS (Complementary MIS) transistor, for example. First, as illustrated in FIG. 5, for example, a semiconductor substrate 1 (wafer W) made of mono-crystalline Si with a resistivity of approximately 10 Ωcm is subjected to a heat treatment at a temperature of approximately 850° C., whereby a thin Si oxide film (pad oxide film (not shown)) with a thickness of approximately 10 nm is formed on its main surface (device forming surface). Subsequently, a Si nitride film 2 having a thickness of approximately 120 nm is deposited on the Si oxide film by a CVD (Chemical Vapor Deposition) method. By using the above-described CVD film forming apparatus according to the present embodiment, the Si nitride film 2 can be deposited with good film quality and well-controlled thickness.

Next, as illustrated in FIG. 6, the Si nitride film 2 and the Si oxide film within an isolation region are removed by dry etching using a photoresist film as a mask. This Si oxide film is formed in order to ease stress exerted on the substrate, for example, at the time when the Si oxide film embedded in an isolation trench is densified (baked) in a subsequent process, etc. Also, since having a property of being hardly oxidized, the Si nitride film 2 is used as a mask for preventing oxidization of the surface of the substrate disposed at the lower portion (active region) thereof. Subsequently, a trench having a depth of approximately 350 nm is formed in the semiconductor substrate 1 within the isolation region by the dry etching using the Si nitride film 2 as a mask. Thereafter, in order to remove, by etching, a damaged layer generated on the inner wall of the trench, the semiconductor substrate 1 is subjected to the heat treatment at approximately 1000° C. to form, on the inner wall of the trench, a thin Si oxide film (not shown in the drawings) having a thickness of approximately 10 nm. Next, for example, a Si oxide film 3 is deposited as an insulator film on the semiconductor substrate 1 by the CVD method, whereby the trench is filled with the Si oxide film 3. By using the above-described CVD film forming apparatus according to the present embodiment, the Si oxide film 3 can be deposited with good film quality and well-controlled thickness. Next, in order to improve the film quality of the Si oxide film 3, the semiconductor substrate 1 is subjected to the heat treatment to densify (bake) the Si oxide film 3.

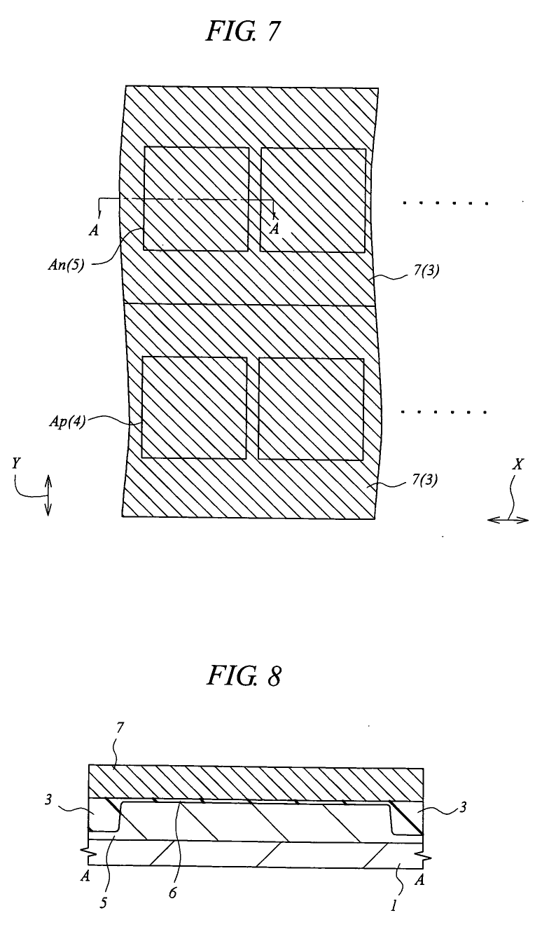

Next, as illustrated in FIGS. 7 and 8, the Si oxide film 3 is polished by the CMP (Chemical Mechanical Polishing) method using the Si nitride film 2 as a stopper so as to be left in the trench, whereby the isolation region of which a surface is planarized is formed.

Next, impurities each having p-type conductivity (for example, boron (B)) and impurities each having n-type conductivity (for example, phosphorus (P)) are ion-implanted into the semiconductor substrate 1. Thereafter, the semiconductor substrate 1 is subjected to the heat treatment at approximately 1000° C. and the above-mentioned impurities are diffused, whereby a p-type well 4 and an n-type well 5 are formed. Active regions An and Ap which are respective main surfaces of the p-type well 4 and the n-type well 5 are formed on the semiconductor substrate 1, and these active regions are each surrounded by an isolation region in which the Si oxide film 3 is embedded. Also, these active regions An and Ap and the isolation region are arranged along X and Y directions shown in FIG. 7.

Next, the main surface of the semiconductor substrate 1 (the p-type well 4 and the n-type well 5) is subjected to wet cleaning by using, for example, a fluoride system cleaning solvent. Thereafter, a gate insulator film 6 composed of a clean oxide film having a thickness of approximately 6 nm is formed on each of the surfaces of the p-type well 4 and the n-type well 5 by thermal oxidation performed at approximately 800° C. At this time, this gate insulator film 6 may be formed by a silicon oxynitride film (SiON film). Therefore, since the occurrence of interface levels in the gate insulator film 6 is suppressed and, simultaneously, electron traps in the gate insulator film 6 are also reduced, hot carrier resistance can be improved. Dut to this, the operation reliability of p-channel type MISFET and n-channel type MISFET can be improved.

Subsequently, by the CVD method, for example, a low-resistant polycrystalline Si film 7 having a thickness of approximately 100 nm is deposited as a conductive film on the upper portion of the gate insulator film 6. By using the above-described CVD film forming apparatus according to the present embodiment, the polycrystalline Si film 7 can be deposited with good film quality and well-controlled thickness.

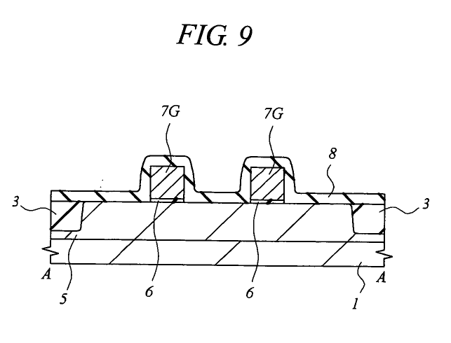

Next, as illustrated in FIG. 9, the polycrystalline Si film 7 is patterned by the dry etching using a photoresist film as a mask to form gate electrodes 7G. The gate electrode 7G may have a so-called polymetal structure, which is formed by, for example, depositing a metal film such as tungsten (W), through a barrier metal film such as titanium nitride (TiN) or tungsten nitride (WN), on an n-type low resistant polycrystalline Si in this order from the bottom. This barrier metal film has a function of, for example, preventing silicide from being produced on its contact portion by the thermal treatment during the manufacturing process when the tungsten film is directly laid on the low-resistant polycrystalline Si film. By adopting the polymetal structure, the resistance of the gate electrodes 7G can be reduced, whereby the operating speed of a gate array can be improved. Also, the gate electrode 7G may have a so-called polycide structure, which is formed by depositing a silicide film such as tungsten silicide on the low-resistant polycrystalline Si film. At both ends of the gate electrode 7G in the longitudinal direction (at positions overlaying the isolation region surrounding the active regions An and Ap), there are formed broad portions at which connection holes for connection with upper wirings are disposed. The gate electrodes 7G are formed by a patterning process employing the same photolithography technology and dry etching technology so as to have the dimension equal to each other. Although not specifically restrictive, the gate length of each gate electrode 7G is, for example, approximately 0.13 μm.

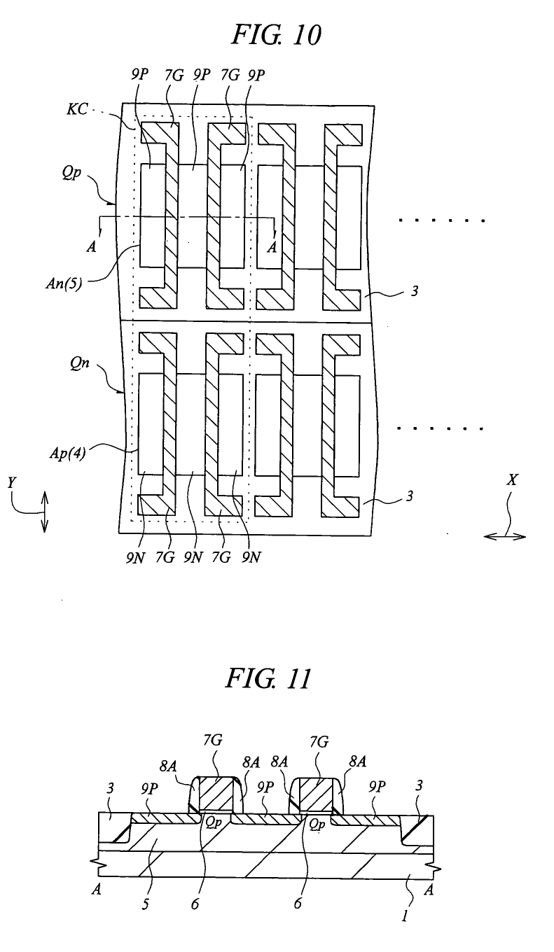

Next, for example, a Si nitride film 8 is deposited over the semiconductor substrate 1. By using the above-described CVD film forming apparatus according to the present embodiment, this Si nitride film 8 can be deposited with good film quality and well-controlled thickness. Subsequently, as illustrated in FIGS. 10 and 11, the Si nitride film 8 is anisotropically etched to form sidewall spacers 8A. Subsequently, impurities each having n-type conductivity (for example, P or As (arsenic)) are ion-implanted into the p-type well 4 to form n-type semiconductor regions (source and drain) 9N, and impurities each having p-type conductivity (for example, B) are ion-planted into the n-type well 5 to form p-type semiconductor regions (source and drain) 9P. Using the above-mentioned processes, it is possible to form a basic cell KC constituting a CMIS gate array, and form the p-channel type MISFET Qp and the n-channel type MISFET Qn constituting the basic cell KC. However, the structure of the basic cell KC is not restricted to the above-described structure, and can be variously modified and altered. For example, a MISFET having a relatively narrow gate width and a MISFET having a relatively wide gate width may be arranged in the single basic cell KC, or MISFETs having different gate electrodes in dimension can be arranged in the single basic cell KC, or the like. Therefore, for example, if the MISFET in which a small drive current flows is intended to be connected to an input of a logic circuit constituted by the MISFET in which a large drive current flows, such connection can be achieved using a short wiring path.

Of the above-mentioned p-type semiconductor regions 9P, one p-type semiconductor region 9P located at their center and between the gate electrodes 7G adjacent and parallel to each other is a region common to two p-channel type MISFETs Qp. Note that, in order to suppress hot carriers, the p-type semiconductor region 9P may have a so-called LDD (Lightly Doped Drain) structure, which includes: a low impurity concentration region disposed on a channel side of the corresponding MISFET; and-a high impurity concentration region electrically connected to the low impurity concentration region and formed by using the sidewall spacer 8A as a mask to ion-implant impurities having n-type conductivity (for example, P or As) into a position which is, only a degree of the low impurity concentration region, away from the channel. Also, in order to suppress a punch-through between the source and the drain, a semiconductor region having conductivity of a type other than that of the p-type semiconductor region 9P may be provided at a position, which is close to an end on the channel side of the p-type semiconductor region 9P and is located at a predetermined depth from the main surface of the semiconductor substrate 1. Even in the n-channel type MISFETs Qn similarly to the p-channel type MISFETs Qp, one n-type semiconductor region 9N disposed at the center of the basic cell KC is a region common to two n-channel type MISFETs Qn. Note that the n-channel type MISFET Qn may have an LDD structure similarly to the p-channel type MISFET Qp, or may have a structure including a p-type semiconductor region for suppressing the punch-through.

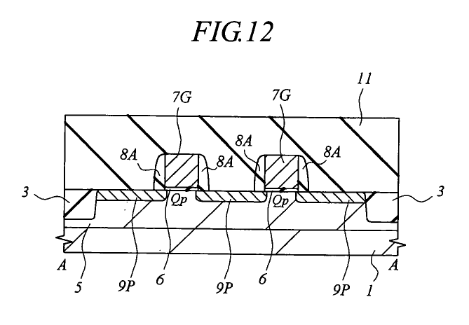

Next, as illustrated in FIG. 12, a Si oxide film is deposited over the semiconductor substrate 1 by the CVD method to form a interlayer insulator film 11. By using the above-described CVD film forming apparatus according to the present embodiment, the Si oxide film to be the interlayer insulator film 11 can be deposited with good film quality and well-controlled thickness. Subsequently, the surface of the interlayer insulator film 11 is polished by the CMP method and is planarized.

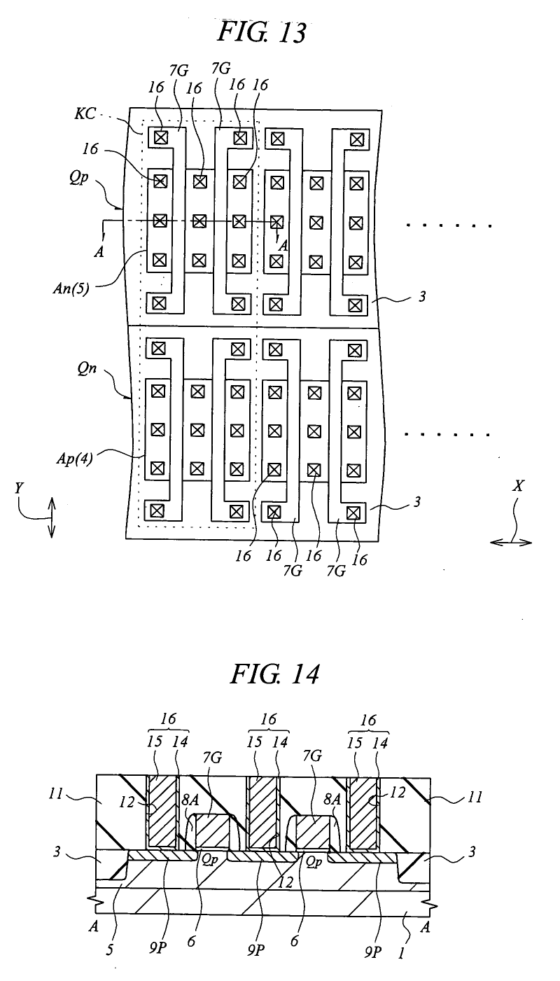

Next, as illustrated in FIGS. 13 and 14, the interlayer insulator film 11 is dry etched using a unshown photoresist film as a mask, whereby n-type semiconductor regions (source and drain) 9N, p-type semiconductor regions (source and drain) 9P, and connection holes 12 each reaching the gate electrode 7G are formed. Each of the connection holes 12 is disposed so as to overlap a broad portion of the gate electrode 7G, and the p-type semiconductor region 9P, and the n-type semiconductor region 9N. Herein, all of the connection holes 12 connectable to the basic cell KC are exemplarily illustrated. In practice, however, the arrangement of the connection holes 12 may be varied for each product. From a bottom of each connection hole 12, parts of the broad portion of the gate electrode 7G and the p-type semiconductor region 9P or n-type semiconductor region 9N are exposed. In a gate array, a pattern including a plurality of basic cells KC as described above is formed as a common one over the semiconductor substrate 1. By connecting the plurality of basic cells KC through hole patterns (connection holes 12 or via holes) and wirings, a desired logic circuit is formed. That is, various logic circuits can be formed depending on the layout of the hole patterns and the wirings.

Next, a Ti film having a thickness of approximately 10 nm and a TiN film having a thickness of approximately 100 nm are sequentially deposited on an upper portion of the interlayer insulator film 11 by, for example, a spattering method. At this time, the Ti and TiN films are deposited also inside the connection holes 12. Subsequently, the semiconductor substrate 1 is subjected to the heat treatment for approximately 1 minute at approximately 500° C. to 700° C., whereby a barrier conductor film 14, formed of a laminated film of the Ti film and the TiN film, is formed.

Next, a W (tungsten) film 15 to be embedded in the connection holes 12 is deposited on an upper portion of the barrier conductor film 14 by, for example, the CVD method. Subsequently, the barrier conductor film 14 and the W film 15 are etched back or polished by the CMP method or the like until the surface of the interlayer insulator film 11 is exposed, and the barrier conductor film 14 and the W film 15 outside the connection holes 12 are removed. Thereby, a plug 16 composed of the barrier conductor film 14 and the W film 15 can be formed in each connection hole 12.

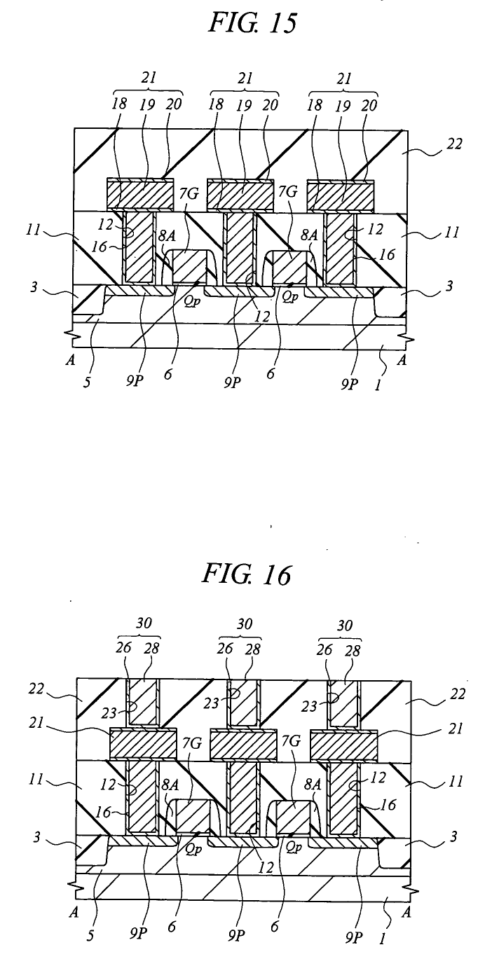

Next, as illustrated in FIG. 15, a Ti (titan) film 18, an Al alloy film 19, and a TiN film 20 are sequentially deposited on the upper portion of the interlayer insulator film 11 by, for example, the spattering method. Herein, either or both of the Ti film 18 and the TiN film 20 may be formed by a laminated film of a Ti film and a TiN film. Subsequently, the Ti film 18, the Al alloy film 19, and the TiN film 20 are patterned by the dry etching using a photoresist film (not shown) as a mask, whereby wirings 21 electrically connected to the p-type semiconductor regions 9P are formed. Although not shown, the same wirings 21 are connected also to the n-type semiconductor regions 9N.

Subsequently, a Si oxide film 21 is deposited on the interlayer insulator film 11 and the wire 21 by, for example, the CVD method, whereby an interlayer insulator film 22 is formed. By using the above-described CVD film forming apparatus according to the present embodiment, a Si oxide film to be the interlayer insulator film 22 can be deposited with good film quality and well-controlled thickness.

Next, as illustrated in FIG. 16, the interlayer insulator film 22 is dry etched using a photoresist film (not shown) as a mask to form connection holes 23 reaching the wirings 21. Subsequently, a Ti film and a TiN film are sequentially deposited on an upper portion of the interlayer insulator film 22 including the interiors of the connection holes 23 by, for example, the spattering method. Subsequently, the semiconductor substrate 1 is subjected to the heat treatment, whereby a barrier conductor film 26 composed of a laminated film of the Ti film and the TiN film is formed. Subsequently, a W film 28 to be embedded in the connection holes 23 is deposited on an upper portion of the barrier conductor film 26 by, for example, the CVD method. Subsequently, the barrier conductor film 26 and the W film 28 are etched back or polished by the CMP or the like until the surface of the interlayer insulator film 22 is exposed, whereby the barrier conductor film 26 and the W film 28 outside the connector holes 23 are removed. Due to this, a plug 30 composed of the barrier conductor film 26 and the W film can be formed in each connector hole 23.

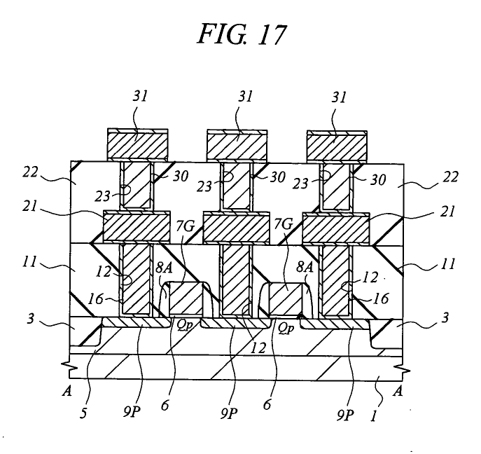

Next, as illustrated in FIG. 17, a Ti film, an Al alloy film, and a TiN film are sequentially deposited on the upper portion of the interlayer insulator film 22 by, for example, the spattering method. Subsequently, the Ti film, the Al alloy film, and the TiN film are patterned by the dry etching using a photoresist film (not shown) as a mask, and thereby wirings 31 to be connected to the plugs 30 are formed. In this manner, the semiconductor device according to the present embodiment is manufactured.

As described above, the inventions made by the present inventors have been concretely described based on the embodiments. However, needless to say, the present invention is not limited to the above-mentioned embodiments and can be variously modified and altered without departing from the gist thereof.

For example, in the above-mentioned embodiments, there has been described the case of preventing the generation of the by-products after the gas cleaning is performed in the furnace body of the CVD film forming apparatus, which performs the film forming process to the wafer in the single wafer processing. However, by performing the same processes also in a batch CVD film forming apparatus performing the film forming process to the plurality of wafers at a time, the generation of the by-products after finishing the gas cleaning in the furnace body can be prevented.

Also, in the above-mentioned embodiments, there has been described an example of the CVD film forming apparatus, which forms an amorphous Si film, a polycrystalline Si film, a Si nitride film, and a Si oxide film in the atmosphere having a high temperature of approximately 600° C. or higher. However, by performing the same processes also in the CVD film forming apparatus, which forms a metal film in the atmosphere having a temperature of approximately 600° C. or higher, the generation of the by-products after finishing the gas cleaning in the furnace body can be prevented.

Furthermore, in the above-mentioned embodiments, there has been described, by way of example, the case where the heater disposed in the furnace body of the CVD film forming apparatus is made of Al system ceramic. However, the heater may be made of SiC (silicon carbide).

Additionally, in the above-mentioned embodiments, there has been described the case of applying the present invention to a CVD film forming apparatus, which forms an amorphous Si film, a polycrystalline Si film, a Si nitride film, and a Si oxide film in the atmosphere having a high temperature of approximately 600° C. or higher. However, the present invention may be applied to a CVD film forming apparatus, which forms a Si nitride film on a glass substrate, in a process of manufacturing a liquid crystal substrate, for example.

Effects obtained from the representative ones of the inventions disclosed by this application will be briefly described as follows.

That is, it is possible to prevent the by-products from being generated in the furnace body after finishing the gas cleaning inside the furnace body (film forming chamber) in the film forming apparatus.

What is claimed is:

1. A semiconductor device manufacturing method using a film forming apparatus having a film forming chamber for performing a film forming process to a semiconductor substrate, the film forming apparatus performing said film forming process at a first temperature, and including a step of forming a first thin film over said semiconductor substrate, the method comprising the steps of:
after forming said first thin film over a predetermined number of said semiconductor substrates,
(a) decreasing a temperature in said film forming chamber up to a second temperature lower than said first temperature;
(b) after said step (a), forming a plasma from a gas containing a halogen system gas, and removing an accretion attached in said film forming chamber by using said plasma; and
(c) after said step (b), cleaning an interior of said film forming chamber in a step of raising the interior of said film forming chamber up to said first temperature,
wherein said film forming apparatus has, in said film forming chamber, a first member reacting with a halogen system element and generating a by-product, and
the method further comprises the step of:
forming a second thin film on an inner wall of said film forming apparatus and on a surface of a member provided in said film forming chamber at the same temperature as that after said accretion is removed in said step (b) or at a temperature before the interior of said film forming chamber reaches said first temperature in said step (c).

2. The semiconductor device manufacturing method according to claim 1,
wherein said first member contains a metal element or silicon.

3. The semiconductor device manufacturing method according to claim 1,
wherein said first temperature is 600° C. or higher, and said second temperature is a temperature at which no reaction of said halogen system element and said first element occurs.

4. The semiconductor device manufacturing method according to claim 3,
wherein said second temperature is 500° C. or lower.

5. The semiconductor device manufacturing method according to claim 1,
wherein said first and second thin films contain silicon.

6. The semiconductor device manufacturing method according to claim 5,
wherein said second thin film includes a thin film of the same type as that of said first thin film.

7. The semiconductor device manufacturing method according to claim 1,
wherein said film forming apparatus performs the film forming process by a chemical film forming method.

8. The semiconductor device manufacturing method according to claim 1,
wherein said semiconductor substrate has a diameter of 300 mm or larger.

9. A film forming method using a film forming apparatus having a film forming chamber for performing a film forming process to a substrate, the film forming apparatus performing said film forming process at a first temperature, and forming a thin film over said substrate, the method comprising the steps of:
after forming said first thin film over a predetermined number of said substrates,
(a) decreasing a temperature in said film forming chamber up to a second temperature lower than said first temperature;
(b) after said step (a), forming a plasma from a gas containing a halogen system gas, and removing an accretion attached in said film forming chamber by said plasma; and
(c) after said step (b), cleaning an interior of said film forming chamber in a step of raising the interior of said film forming chamber up to said first temperature,
wherein said film forming apparatus has, in said film forming chamber, a first member reacting with a halogen system element and generating a by-product, and
the method further comprises the step of:
forming a second thin film on an inner wall of said film forming apparatus and on a surface of a member provided in said film forming chamber at the same temperature as that after said accretion is removed in said step (b) or at a temperature before the interior of said film forming chamber reaches said first temperature in said step (c).

10. The film forming method according to claim 9,
wherein said first member contains a metal element or silicon.

11. The film forming method according to claim 9,
wherein said first temperature is 600° C. or higher, and said second temperature is a temperature at which no reaction of said halogen system element and said first element occurs.

12. The film forming method according to claim 11,
wherein said second temperature is 500° C. or lower.

13. The film forming method according to claim 9,
wherein said film forming apparatus performs the film forming process by a chemical film forming method.

14. The film forming method according to claim 9,
wherein said semiconductor substrate has a diameter of 300 mm or larger.
